(19) United States
(12) Patent Application Publication
(10) Pub. No.: US 2015/0334839 A1
(43) Pub. Date: Nov. 19, 2015

(54) COMPONENT-FIXING METHOD, CIRCUIT SUBSTRATE, AND DISPLAY PANEL

(71) Applicant: SHARP KABUSHIKI KAISHA, Osaka-shi, Osaka (JP)

(72) Inventors: Hiroki NAKAHAMA, Osaka-shi (JP); Motoji SHIOTA, Osaka-shi (JP); Takashi MATSUI, Osaka-shi (JP); Hiroki MIYAZAKI, Osaka-shi (JP); Masaki NAKAYAMA, Osaka-shi (JP)

(21) Appl. No.: 14/652,175

(22) PCT Filed: Dec. 6, 2013
(86) PCT No.: PCT/JP2013/082767

§ 371 Date: Jun. 15, 2015

(30) Foreign Application Priority Data
Dec. 20, 2012 (JP) 2012-277802

(51) Int. Cl. H05K 1/18; B32B 37/12; B32B 37/18; H05K 1/11

(52) U.S. Cl. CPC H05K 1/181; H05K 1/111; B32B 37/1284; B32B 37/18; H05K 2201/10136; B32B 2037/1253; B32B 2307/202; B32B 2307/412; B32B 2310/0831; B32B 2457/08

(57) ABSTRACT

The present invention involves forming wiring sections on a substrate capable of UV-ray transmission, and fixing a component to be electrically connected to the wiring sections onto the substrate using a UV-curable ACF. When doing so, fluidity in the UV-curable ACF is produced by applying pressure to the component, and UV rays are directly projected from the surface of the substrate even onto the UV-curable ACF areas shielded by the wiring sections. The UV-curable ACF is made to be fluid by applying pressure to the component after increasing fluidity of the UV-curable ACF by heating.

### TECHNICAL FIELD

The present invention relates to a method of fixing a component, a circuit substrate including a component fixed by the method, and a display panel including the circuit substrate.

### BACKGROUND ART

A display panel such as a liquid crystal display panel or an organic EL display panel is assembled into a module along with components such as a driver IC for driving it and a flexible printed circuit (FPC). Generally, a display panel is assembled into a module by a method in which, to an electrode formed on a substrate surface of a display panel, a component is electrically connected and simultaneously physically fixed by an anisotropic conductive film (hereinafter referred to as ACF in the present specification and the appended claims). One example is disclosed in Patent Document 1.

According to the production method of a liquid crystal display device described in Patent Document 1, an ACF that includes as adhesive a resin that cures with either ultraviolet rays (UV light) or heat is used for connecting a TCP (tape carrier package) or a flexible printed circuit to a liquid crystal display element. First, connection electrodes of the liquid crystal display element and electrodes of the TCP or the flexible printed circuit are placed opposite each other; then, a pressure is applied; then, an adhesive layer of the ACF is irradiated for a predetermined time with a predetermined amount of UV light from the liquid crystal display element side. Thus, the adhesive of the ACF in an area where the connection electrodes of the liquid crystal display element do not shield light hardens through a photo-curing reaction. Then, the TCP or the flexible printed circuit is subjected to permanent thermocompression; here, the cured adhesive suppresses a flow in the conductive film, and this ensures that the electrodes of the TCP or the flexible printed circuit conduct to the connection electrodes of the liquid crystal display element.

### LIST OF CITATIONS

### Patent Literature

Patent Document 1: JP-A-2000-105388

### SUMMARY OF THE INVENTION

### Technical Problem

With the production method of a liquid crystal display device described in Patent Document 1, the ACF is cured with both UV light and heat and, inconveniently, the heat causes a component and a substrate to warp. Nowadays, liquid crystal display panels are in a trend toward an ever smaller area outside a display portion so as to attain a narrow frame, and thus the distances between the display portion and a driver IC and between the driver IC and a FPC are becoming increasingly small. The smaller distances cause the heat for curing the ACF to produce adverse effects. For example, display quality can deteriorate, and the driver IC and the FPC can have lower connection reliability.

Thus, recently, an UV-curable ACF, with which curing progresses only with UV light, is increasingly used. Using an UV-curable ACF makes it possible to connect and fix a component at comparatively low temperature, and thus makes it less likely for heat to damage a component or a substrate. Moreover, it is possible to reduce the time required to raise temperature to a target temperature, and thus, advantageously, it is possible to improve production efficiency.

On the other hand, an UV-curable ACF causes the following inconveniences. If part of an ACF is located at where a conductor (in the present specification, the term “conductor” is used to cover both electrodes for electrically connecting a component and those for connecting electrodes together) shields light, that part, if it is a part of the ACF described in Patent Document 1, can be cured by heating but, if it is a part of an UV-curable ACF, cannot be cured by a process of heating. The part of the ACF located at where light is shielded does cure to some degree with UV light propagating inside the ACF by reflection, but it cures so incompletely as to be evaluated as uncured.

An uncured ACF does not function properly and rather produces adverse effects, such as low adhesion between a component and a substrate, high electric resistance due to small curing shrinkage, and change in hygroscopicity. The uncured ACF readily absorbs moisture, inconveniently leading to corrosion of a metal conductor on a substrate surface, and high electric resistance resulting from the substrate swelling by absorbing moisture. To achieve component mounting with high reliability, an ACF needs to be cured with a rate of reaction higher than a given rate in every part of it. The given rate, though depending on the type of ACF, is generally eighty percent or more.

Devised against the background discussed above, the present invention is directed to the fixing of a component by use of an UV-curable ACF, and aims to leave no part of the ACF uncured by irradiating even a part of the UV-curable ACF located at where a conductor shields light directly with UV light.

### Means for Solving the Problem

According to one aspect of the present invention, a method of fixing a component, involving forming a conductor on a substrate that transmits UV light, and electrically connecting the component to the conductor and simultaneously fixing the component to the substrate with a UV-curable ACF, includes the steps of: producing a flow in the UV-curable ACF by applying a pressure to the component, and irradiating the UV-curable ACF with UV light from the reverse side of the substrate such that even part of the UV-curable ACF located at where the conductor shields the UV light is directly irradiated by the UV light.

The above-described method of fixing a component preferably further includes a step of: applying a pressure to the component after increasing the fluidity of the UV-curable ACF by heating.

The above-described method of fixing a component preferably further includes a step of: performing irradiation with the UV light before the UV-curable ACF starts to flow.

The above-described method of fixing a component preferably further includes a step of: performing irradiation with the UV light while the UV-curable ACF is flowing.

According to another aspect of the present invention, a circuit substrate includes a component fixed by any of the methods described above.

In the circuit substrate described above, preferably, the conductor to which the component is connected is arranged displaced from the center of a mounting portion of the component.

In the circuit substrate described above, preferably, the conductor to which the component is connected has an opening formed at a place aligned with a center of a mounting portion of the component.

In the circuit substrate described above, preferably, the conductor to which the component is connected has a plurality of openings formed in a distributed fashion in an area that includes the center of a mounting portion of the component.

According to yet another aspect of the present invention, a display panel includes any of the circuit substrates described above.

### Advantageous Effects of the Invention

According to the present invention, a flow is produced in a UV-curable ACF by applying a pressure to a component, and even a part of the UV-curable ACF located at where a conductor shields light is directly irradiated with UV light from the reverse side of a substrate. It is thus possible to leave no part of the ACF unirradiated with UV and hence uncured, and thereby to overcome inconveniences resulting from part of the UV-curable ACF remaining uncured.

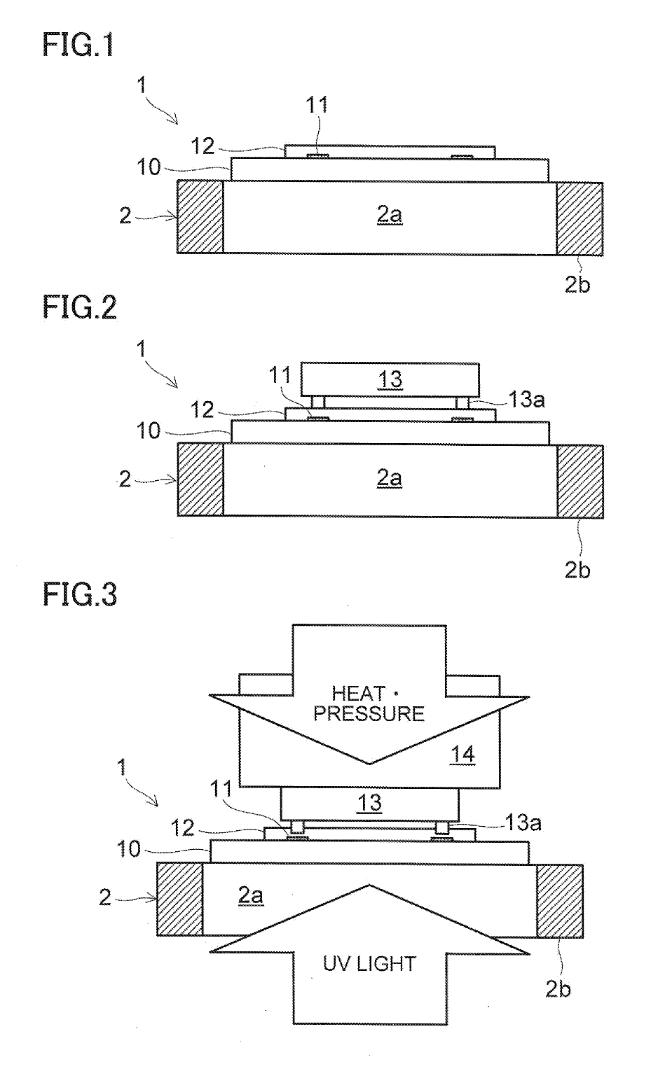

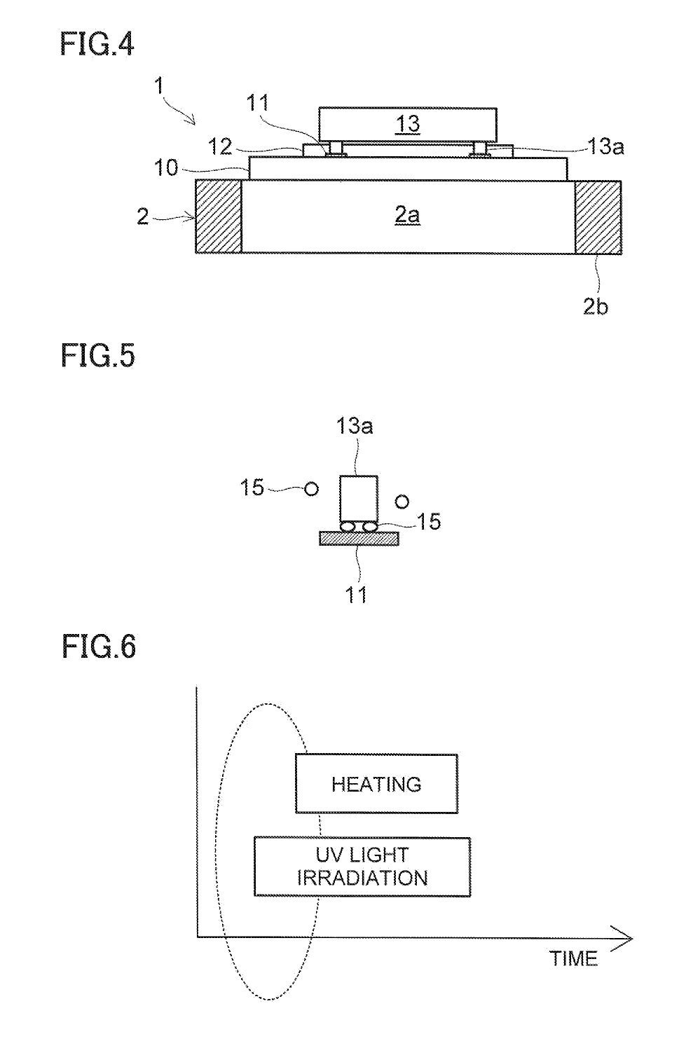

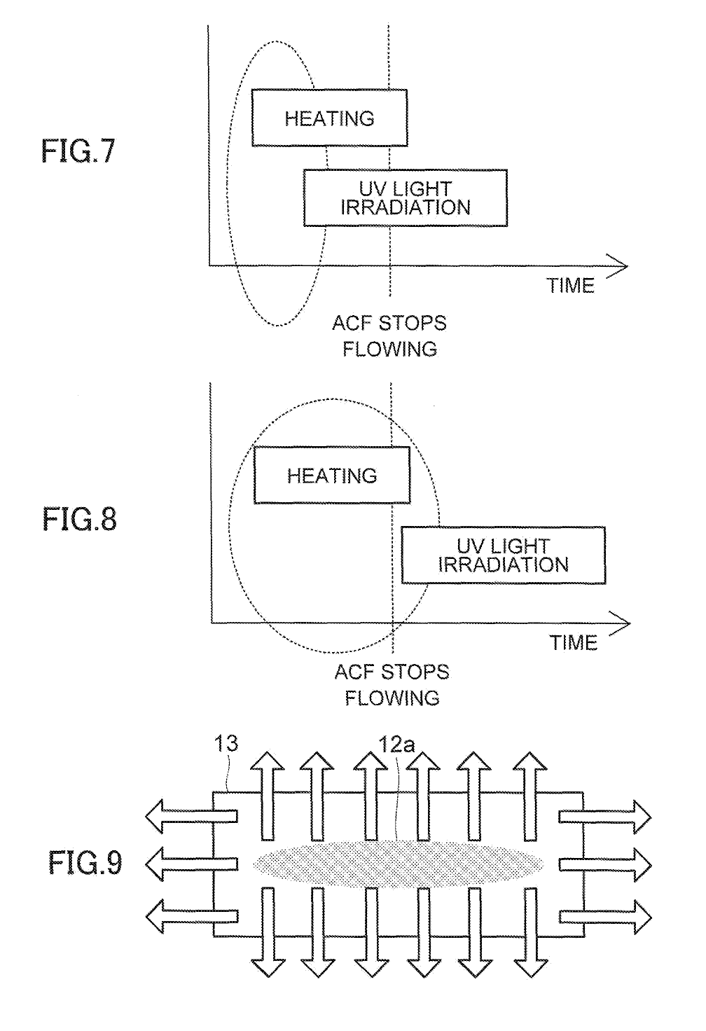

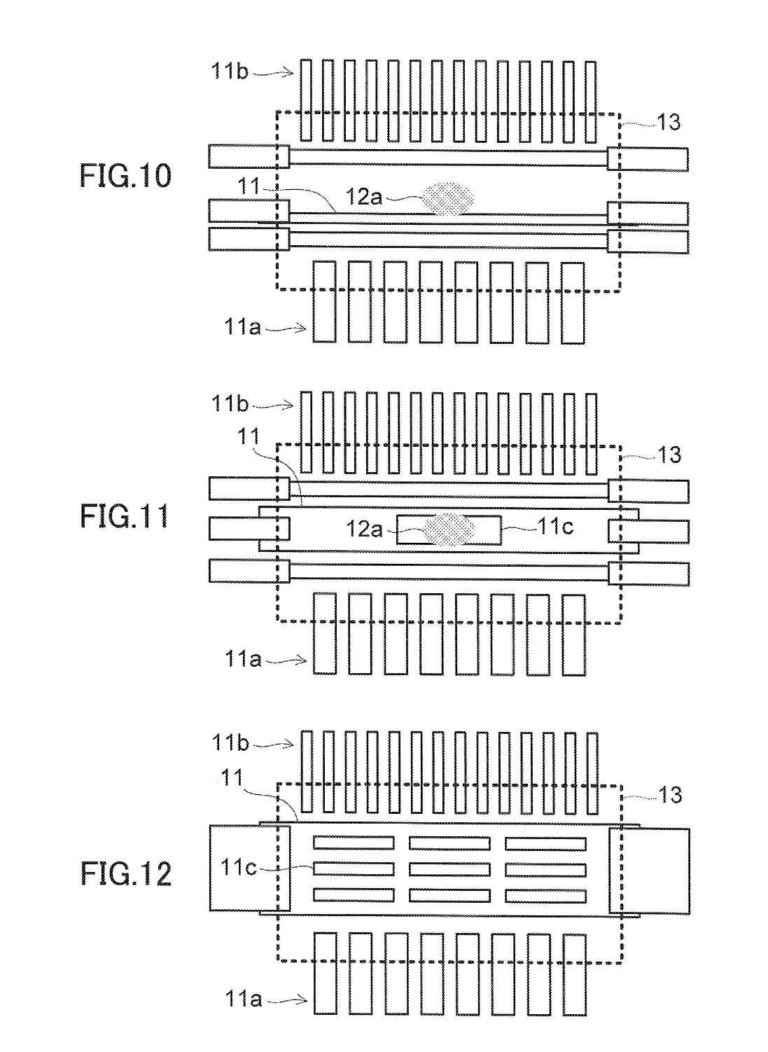

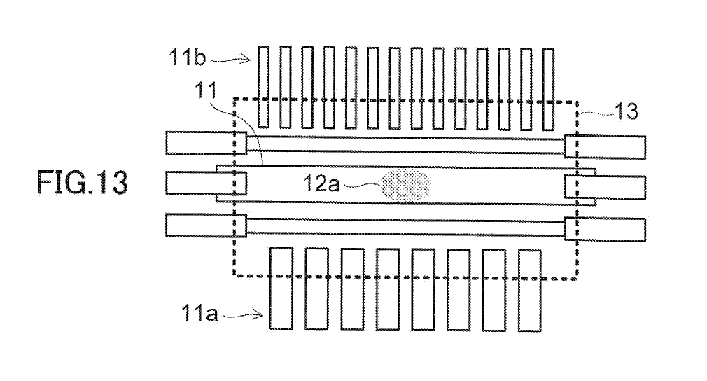

### BRIEF DESCRIPTION OF DRAWINGS

[FIG. 1] A first diagram illustrating a method of fixing a component according to the present invention.

[FIG. 2] A second diagram illustrating a method of fixing a component according to the present invention.

[FIG. 3] A third diagram illustrating a method of fixing a component according to the present invention.

[FIG. 4] A fourth diagram illustrating a method of fixing a component according to the present invention.

[FIG. 5] A diagram illustrating an electrical connection by an UV-curable ACF.

[FIG. 6] A first Gantt chart illustrating a timing of irradiation with UV light.

[FIG. 7] A second Gantt chart illustrating a timing of irradiation with UV light.

[FIG. 8] A third Gantt chart illustrating timing of irradiation with UV light.

[FIG. 9] A diagram illustrating a flow in an UV-curable ACF.

[FIG. 10] A plan view showing a first configuration example of a conductor.

[FIG. 11] A plan view showing a second configuration example of a conductor.

[FIG. 12] A plan view showing a third configuration example of a conductor.

[FIG. 13] A plan view showing an undesirable configuration example of a conductor.

### DESCRIPTION OF EMBODIMENTS

First, with reference to FIGS. 1 to 4, an outline of a component-fixing method according to the present invention will be described.

A component-fixing method according to the present invention is performed by use of a component-fixing device 1. A main component of the component-fixing device 1 is a horizontal stage 2. The stage 2 has a structure in which a stage central portion 2a made of a material that transmits UV light, such as glass, is supported by a stage peripheral portion 2b made of metal.

As shown in FIG. 1, on the stage central portion 2a, a substrate 10 that transmits UV light is placed. As an example of the substrate 10, a TFT glass substrate of a liquid crystal display panel is shown. On a surface of the substrate 10, a conductor 11 made of a metal with low electric resistance is formed, and a UV-curable ACF 12 is adhered so as to cover the conductor 11. The conductor 11 does not transmit light, and thus serves as a light-shielding portion for UV light.

The UV-curable ACF 12 is supplied in a form, like double-sided adhesive tape, adhered to an unillustrated separator and wound into a reel. Whereas the separator is in a form of continuous tape, the UV-curable ACF 12 has splits at predetermined intervals. A portion of the UV-curable ACF 12 with a predetermined length from one split to the next is put in contact with the substrate 10, and heat and pressure are applied to the portion from above across the separator. In this way, while the UV-curable ACF 12 adheres to the substrate 10, the separator separates from the UV-curable ACF 12, leaving only the UV-curable ACF 12 neatly transferred to the substrate 10.

As shown in FIG. 2, a component is mounted on a top surface of the UV-curable ACF 12. Although the component may be an FPC or a TCP, here, an IC 13 is shown as an example. The IC 13 is mounted on the conductor 11 by a COG (chip on glass) process. At this stage, the IC 13 is simply positioned within a horizontal plane and placed lightly on the UV-curable ACF 12. Bumps 13a are formed on a bottom surface of the IC 13 to serve as terminals. The UV-curable ACF 12 serves to electrically connect the bumps 13a to the conductor 11 and to physically fix the IC 13 to the substrate 10.

As shown in FIG. 3, the IC 13 is heated by a heater tool 14. The heating reduces the viscosity of the UV-curable ACF 12, which thus liquefies; that is, the fluidity of the UV-curable ACF 12 increases. After so heating the UV-curable ACF 12 and increasing its fluidity, a pressure is applied to the UV-curable ACF 12 by the heater tool 14 to make the UV-curable ACF 12 flow. It is preferable that the IC 13 be heated so as to raise the temperature of the UV-curable ACF 12 to 70° C. to 100° C. The pressure applied to the UV-curable ACF 12 can be approximately equal to the pressure during thermocompression bonding using a thermosetting ACF.

The heat from the heater tool 14 is expended not for curing the UV-curable ACF 12 but only for making it flow. This requires an amount of heat smaller than that required for curing the UV-curable ACF 12. This allows the IC 13 to be mounted at lower temperature, and mounting it at lower temperature helps alleviate warping of the IC 13 and of the substrate 10. In a case where the substrate 10 is one to be incorporated in a display panel, improved display quality results.

The part of the fluidized UV-curable ACF 12 located at where the conductor 11 shields light is pushed out of the place by being pressed by the bumps 13a. As the pressing of the IC 13 progresses, the IC 13 itself begins to press the UV-curable ACF 12, producing a large-scale flow inside the UV-curable ACF 12. Also by this large-scale flow, the part of the UV-curable ACF 12 located at where the conductor 11 shields light is pushed out of the place.

While the bumps 13a are approaching the conductor 11 under the pressure from the heater tool 14, an unillustrated UV light source arranged under the stage 2 emits UV light and irradiates the UV-curable ACF 12 with the UV light from the reverse side of the substrate 10.

Not only the part of the UV-curable ACF 12 located at where the conductor 11 does not shield light, but also the part of the UV-curable ACF 12 which would stay at where the conductor 11 shields light without the flow is irradiated directly with UV light by being pushed out of the place where the conductor 11 shields light as the result of the flow. Here, “direct irradiation” refers not to irradiation with UV light propagating inside the UV-curable ACF 12 by reflection, but to irradiation with UV light from the UV light source with no interception on the way.

The UV-curable ACF 12 begins to cure by being irradiated directly with UV light. Although part of the UV-curable ACF 12 is moved by the flow to where the conductor 11 shields light, this is the part of the UV-curable ACF 12 that has been located at where the conductor 11 does not shield light and it has already been irradiated directly with UV light, so that it also begins to cure.

As described above, the phrase “the UV-curable ACF located at where the conductor shields light” has two meanings: it means, first, the part of the UV-curable ACF which, without the flow, would stay at where the conductor shields light but which, because of the flow, is pushed out of the place where the conductor does not shield light; second, the part of the UV-curable ACF which is located at where the conductor does not shield light but which is moved, by the flow, to where the conductor shields light. Irrespective of which part it means, the UV-curable ACF 12 is irradiated directly with UV light, and thus such part of the UV-curable ACF 12 as would otherwise be left uncured is removed. In this way, it is possible to overcome the inconvenience that could result from part of the uncured UV-curable ACF 12 remaining uncured.

FIG. 4 shows a stage after completion of the heating and pressing of the IC 13 and the irradiation of the UV-curable ACF 12 with UV light. The thickness of the UV-curable ACF 12 is designed to be larger than the height of the bumps 13a so as to prevent the space between the IC 13 and the substrate 10 from being incompletely filled with the UV-curable ACF 12. Thus, when the IC 13 is pressed until the bumps 13a approach the conductor 11, part of the UV-curable ACF 12 becomes surplus, which has to be removed. The surplus part of the UV-curable ACF 12 is removed outside the IC 13, and the bumps 13a and the conductor 11 are connected together electrically via the UV-curable ACF 12.

FIG. 5 conceptually shows how conductive particles 15 inside the UV-curable ACF 12 are pressed and flattened between the conductor 11 and the bumps 13 to establish conduction between the conductor 11 and the bumps 13. This state is maintained owing to the UV-curable ACF 12 curing through irradiation with UV light.

Now, how the setting of the timing of heating the IC 13 and irradiating it with UV light influences the fixing of the IC 13 will be described with reference to Gantt charts in FIGS. 6 to 8.

The setting of timing shown in FIG. 6 will be referred to as a first embodiment, the setting of timing shown in FIG. 7 will be referred to as a second embodiment, and the setting of timing shown in FIG. 8 will be referred to as a first comparative example.

### First Embodiment

In FIG. 6, irradiation with UV light starts before the IC 13 is heated. Previously irradiated with UV light, the UV-curable ACF 12 increases its fluidity through the subsequent heating, and thus flows under pressure.

By irradiating the UV-curable ACF 12 with UV light before it starts to flow, it is possible to move the UV-curable ACF 12 that has absorbed sufficient UV light. However, if the UV-curable ACF 12 absorbs an excessive amount of UV light, its curing progresses and its viscosity increases. This prevents it from fluidizing through the subsequent heating. Though depending on the resin material of the UV-curable ACF 12, the time-lag between the start of irradiation with UV light and the start of heating is preferably one second or less.

### Second Embodiment

In FIG. 7, irradiation with UV light starts after the IC 13 is heated. Having started to flow under pressure after heating, the UV-curable ACF 12 continues to flow while being irradiated with UV light, and absorbs UV light. When the UV-curable ACF 12 cures through irradiation with UV light, it stops flowing even before completion of heating and pressing.

Though depending on the resin material of the UV-curable ACF 12, preferably, the time of irradiation with UV light is about three to ten seconds, and the time-lag between the start of heating and the start of irradiation with UV light is one second or less.

### First Comparative Example

In FIG. 8, irradiation with UV light starts when the heating and pressing of the IC 13 are almost over and after the UV-curable ACF 12 stops flowing. In this case, since the flow of the UV-curable ACF 12 has stopped, the UV-curable ACF 12 irradiated with UV light does not move.

If any part of the UV-curable ACF 12 cures incompletely, that is because the conductor portion 11 shields UV light and prevents it from reaching the UV-curable ACF 12. If irradiation with UV light is performed after the UV-curable ACF 12 stops flowing as shown in FIG. 8, the part of the UV-curable ACF 12 located at where the conductor portion 11 shields light ends up never being irradiated directly with UV light.

On the other hand, when irradiation with UV light is timed as in the first embodiment (FIG. 6) and the second embodiment (FIG. 7), since part of the UV-curable ACF 12 located at where the conductor 11 shields light moves, every part of the UV-curable ACF 12 passes through where it is directly irradiated with UV light. Thus, irrespective of whether irradiation with UV light is performed before the UV-curable ACF 12 starts to flow as in the first embodiment or irradiation with UV light is performed while the UV-curable ACF 12 is flowing as in the second embodiment, the part of the UV-curable ACF 12 located at where the conductor 11 shields light can be directly irradiated with UV light.

When the IC 13 is heated and then pressed, in the space between the IC 13 and the substrate 10, the UV-curable ACF 12 flows in directions indicated by arrows in FIG. 9 and the surplus part of the UV-curable ACF 12 is removed. However, in a central part of the IC 13, while a surplus part of the UV-curable ACF 12 moves out, very little of it moves in from elsewhere; as a result, part 12a of the UV-curable ACF 12 (indicated by hatching in FIG. 9) is left behind from the flow. A problem associated with part 12a of the UV-curable ACF 12 being left behind from the flow will be described below by way of a second comparative example with reference to FIG. 13. Solutions to the problem will be described below by way of third, fourth, and fifth embodiments with reference to FIGS. 10, 11, and 12 respectively.

### Second Comparative Example

In FIG. 13, a conductor 11 that passes through a central portion of the IC 13 is so configured as to connect together the electrodes arranged on the right and left, and a part of the conductor 11 is located right under the part 12a of the UV-curable ACF 12 that is left behind from the flow. With this configuration, the part 12a of the UV-curable ACF 12 left behind from the flow remains unirradiated with UV light because of the conductor 11 shielding it, and thus ends up uncured. To avoid that, the conductor 11 can be configured ingeniously as shown in any of FIGS. 10 to 12. In FIG. 13 and in FIGS. 10 to 12, the reference sign 11a identifies a signal input electrode portion which is connected to an unillustrated FPC to receive signals, and the reference sign 1 lb identifies a signal output electrode portion which is connected to an unillustrated display area of a liquid crystal display panel. Only the position of the IC 13, which is a component to be fixed by the UV-curable ACF 12, is shown by a dashed-line, and the area surrounded by the dashed-line is the mounting portion (COG mounting portion) of the IC 13.

### Third Embodiment

In the configuration shown in FIG. 10, no conductor 11 passes through the center of the mounting portion of the IC 13. Even a conductor 11 that passes closest to the center of the mounting portion of the IC 13 is displaced by a small distance from the central mounting portion. Thus, the part 12a of the UV-curable ACF 12 left behind from the flow is directly irradiated with UV light without the conductor 11 shielding it, and thus cures.

### Fourth Embodiment

In the configuration shown in FIG. 11, one opening 11c is formed in a wide conductor 11 which passes through the center of the mounting portion of the IC 13, at a place aligned with the center of mounting portion. The opening 11c is in a rectangular shape and its longitudinal direction is aligned with the longitudinal direction of the conductor 11. Thus, even the part 12a of the UV-curable ACF 12 left behind from the flow cures by being irradiated directly with UV light through the opening 11c.

### Fifth Embodiment

In the configuration shown in FIG. 12, a plurality of openings 11c are arrayed in a distributed fashion in a wide conductor 11 which passes through the center of the mounting portion of the IC 13. The plurality of the openings 11c are arrayed in a distributed fashion in an area that includes the center of the mounting portion. The part of the UV-curable ACF left behind from the flow cures by being irradiated directly with UV light through one of the plural of the openings 11c arrayed in a distributed fashion.

In FIG. 12, rectangular openings 11c of which the longitudinal direction is aligned with the longitudinal direction of the conductor 11 are arrayed in three rows and in three columns, in a matrix-like formation. This arrangement, however, is only illustrative and is not meant to limit the invention. The intervals between the openings 11c are, both in the up/down and left/right directions in FIG. 12, preferably 0.5 mm or less, and more preferably 0.2 mm or less.

Although in the above description a TFT glass substrate of a liquid crystal display panel is taken up as an example of a substrate 10 which becomes a circuit substrate when mounted with components, this is not meant as any limitation; the present invention may be applied to a glass substrate of an organic EL display panel. The present invention may be applied also to circuit substrates in general which are not intended for incorporation in display panels.

The embodiments by way of which the present invention is described above are in no way meant to limit the scope of the present invention, which thus allows for many modifications and variations within the spirit of the present disclosure.

### INDUSTRIAL APPLICABILITY

The present invention finds wide application in display panels and in circuit substrates in general.

### LIST OF REFERENCE SIGNS

1 component-fixing device
2 stage
10 substrate

11 conductor
11c opening
12 UV-curable ACF
12a UV-curable ACF left behind from flow
13 IC
13a bump
14 heater tool

1. A method of fixing a component, the method including forming a conductor on a substrate that transmits UV light, and electrically connecting the component to the conductor and simultaneously fixing the component to the substrate with a UV-curable ACF, the method comprising the steps of:
producing a flow in the UV-curable ACF by applying a pressure to the component; and
irradiating the UV-curable ACF with UV light from a reverse side of the substrate such that even part of the UV-curable ACF located at where the conductor shields the UV light is directly irradiated by the UV light.

2. The method of claim 1, further comprising the step of:
applying a pressure to the component after increasing fluidity of the UV-curable ACF by heating.

3. The method of claim 1 or 2, further comprising the step of:
performing irradiation with the UV light before the UV-curable ACF starts to flow.

4. The method of claim 1 or 2, further comprising the step of:
performing irradiation with the UV light while the UV-curable ACF is flowing.

5. A circuit substrate comprising a component fixed by the method of claim 1.

6. The circuit substrate of claim 5,
wherein the conductor to which the component is connected is arranged displaced from a center of a mounting portion of the component.

7. The circuit substrate of claim 5,
wherein the conductor to which the component is connected has an opening formed at a place aligned with a center of a mounting portion of the component.

8. The circuit substrate of claim 5,
wherein the conductor to which the component is connected has a plurality of openings formed in a distributed fashion in an area that includes a center of a mounting portion of the component.

9. A display panel comprising: a circuit substrate of claim 5.
